(19) United States
(12) Patent Application Publication
(10) Pub. No.: US 2004/0099205 A1
(43) Pub. Date: May 27, 2004

(54) Method of growing oriented calcium fluoride single crystals

(76) Inventors: Qiao Li, Westborough, MA (US); Frederick E. Noll, Horseheads, NY (US); Gail A. Rodriguez, Bath, NY (US); William R. Rosch, Sturbridge, MA (US); Paul M. Schermerhorn, Painted Post, NY (US); Shane M. Stephens, Port Crane, NY (US)

Correspondence Address: CORNING INCORPORATED, SP-TI-3-1, CORNING, NY, 14831

(21) Appl. No.: 10/652,013

(22) Filed: Aug. 29, 2003

Related U.S. Application Data
(60) Provisional application No. 60/408,154, filed on Sep. 3, 2002.
(60) Provisional application No. 60/408,116, filed on Sep. 3, 2002.

(51) Int. Cl. C30B 1/00

(52) U.S. Cl. 117/2

(57) ABSTRACT

A method of making an oriented calcium fluoride single crystal includes loading calcium fluoride feedstock on top of a seed crystal having a specific crystallographic orientation, heating the calcium fluoride feedstock to a temperature sufficient to form a melt, and growing a calcium fluoride crystal on the seed crystal by progressively moving the melt and the seed crystal through a temperature gradient zone having an axial temperature gradient in a range from approximately 2° C./cm to approximately 8° C./cm, wherein a growth direction of the calcium fluoride crystal substantially conforms to the crystallographic orientation of the seed crystal.

### CROSS-REFERENCE TO RELATED APPLICATIONS

This application claims priority from U.S. Provisional Application Ser. No. 60/408,154, filed Sep. 3, 2002, entitled “A Method to Grow [100] Oriented CaF₂ Single Crystals” and from U.S. Provisional Application Ser. No. 60/408,116, filed Sep. 3, 2002, entitled “A Method to Grow [110] Oriented CaF₂ Single Crystals.”

### BACKGROUND OF INVENTION

Microlithography is used in semiconductor manufacturing to define patterns on integrated circuits. A microlithography system includes an illumination system and a projection system. The illumination system typically includes an excimer laser, which is used to irradiate a mask containing a circuit pattern. The projection system typically includes several projection lenses with highly complex objectives for imaging the circuit pattern onto a wafer. The smallest feature size, F, that can be imaged is determined by the following expression:

$$F = \frac{{k}_{1} λ}{N A} \qquad ( 1 )$$

where k₁ is a process-dependent parameter, typically having a value of 0.5, λ is the illumination wavelength, and NA is the numerical aperture of the objective. From equation (1), the resolution of the microlithography system, i.e., the smallest feature size that can be imaged, can be increased by decreasing the illumination wavelength, λ, and/or increasing the numerical aperture, NA. However, because the depth of focus decreases as numerical aperture increases, it is usually easier to increase resolution by decreasing illumination wavelength.

The industry presently uses 248-nm microlithography systems to image feature sizes larger than 0.25 μm and is preparing to transition to 193-nm microlithography systems that can image feature sizes 0.25 μm and smaller. The industry is also actively developing 157-nm microlithography systems to image feature sizes as small as 100 nm. Successful transition to the 193-nm systems and development of the 157-nm systems depend on the availability of lens materials with high transparency at these wavelengths as well as low birefringence, low residual index inhomogeneity, low anisotropy, and ability to withstand prolonged irradiation without changes in optical properties. Unfortunately, there are not many lens materials that meet these requirements at wavelengths below 200 nm. Fused silica, which is used as lens material in the 248-nm microlithography system, can be used in 193-nm microlithography, although the safety margin for absorption at this wavelength is very small. Fused silica is not transparent enough to be used in 157-nm microlithography.

Up to date, calcium fluoride (CaF₂) single crystal is the most viable lens material for 157-nm microlithography. CaF₂ has high transparency at this wavelength and the ability to withstand prolonged irradiation at this wavelength without its optical properties changing. As a cubic crystalline material, a CaF₂ single crystal is generally presumed to be isotropic and non-birefringent. However, recent findings indicate that a CaF₂ single crystal has anisotropic, birefringent behavior at short wavelengths because of symmetry-breaking. According to Burnett et al., intrinsic birefringence in CaF₂ single crystal at 157 nm is 11.2±0.4 nm/cm in the [110] direction, which is more than ten times the 1 nm/cm target birefringence for 157-nm microlithography. (Burnett, John. H., Levine, Zachary. H., & Shirley, Eric. L. “Intrinsic Birefringence in Crystalline Optical Materials: A New Concern for Lithography.” Future FAB International 12 (2002): 150-154.) Fortunately, intrinsic birefringence has symmetry and specific orientations with respect to the crystallographic orientations, which can be exploited to achieve birefringence reduction. For example, intrinsic birefringence can be compensated for in lens design by combining and clocking [111]- and [100]-oriented CaF₂ single crystal lens elements. (Dana, Stephane. “Progress Report: 157-nm Lithography Prepares to Graduate.” OE Magazine Feb. 2003: 12-14.) Intrinsic birefringence may also be compensated for in lens design by combining and clocking [100]- and [110]-oriented CaF₂ single crystal lens elements.

From the foregoing, it is obvious that high-quality [111]-, [110]-, and [100]-oriented CaF₂ single crystals are needed to enable flexibility in microlithography lens design. [111]-oriented CaF₂ single crystals are readily available and are commonly grown using the Bridgman-Stockbarger process. The process involves a crucible containing CaF₂ feedstock in a hot zone in a two-zone vertical furnace. A [111]-oriented seed crystal is mounted in a seed crystal holder at the bottom of the crucible with the upper portion of the seed crystal in contact with the feedstock. The crucible is heated to melt the feedstock. The crucible is then slowly lowered into a cold zone in the vertical furnace, the cold zone being at a lower temperature than the hot zone. As the crucible moves into the cold zone, the molten fluoride passes through a temperature gradient zone. A crystal front conforming to the crystallographic orientation of the seed crystal is created as the temperature of the molten fluoride drops below the melting point. The crystal propagates inside the crucible, within the molten fluoride, as long as the crucible continues to move downwardly into the cold zone. The crystal is usually annealed once the crucible is fully in the cold zone and/or post-annealed in a separate furnace to reduce stress-induced birefringence to an acceptable level.

Due to difficulty and low yield of [110]- and [100]-oriented CaF₂ single crystal growth, [110]- and [100]-oriented CaF₂ single crystals are usually made by cutting them out of [111]-oriented CaF₂ single crystals. This method of making [110]- and [100]-oriented CaF₂ single crystals is not only inefficient but also greatly limits the size of the [110]- and [100]-oriented lens elements that can be obtained and increases the cost of production. Another challenge for the [110]- and [100]-oriented CaF₂ single crystal growth is high stress-induced birefringence. Due to a higher stress optical coefficient in the [110] and [100] directions, [110]- and [100]-oriented CaF₂ single crystals are expected to yield a higher stress-induced birefringence. (Burnett, J. H., Levine, Z. H., & Shirley, E. L. Intrinsic Birefringence in Calcium Fluoride and Barium Fluoride. Physical Review B 64, 241102 (2001).) It would be beneficial to have the average stress-induced birefringence of [110]- and [100]-oriented CaF₂ single crystals be as low as that of the [111]-oriented CaF₂ single crystals. [111]-oriented CaF₂ single crystals with average stress-induced birefringence better than 1 nm/cm are now available.

From the foregoing, there is desired a method of economically growing CaF₂ single crystals along the [110] and [100] directions, respectively, the grown crystals preferably having stress-induced birefringence sufficiently low to allow their usage in making optical elements for 157-nm microlithography process.

### BRIEF SUMMARY OF INVENTION

In one aspect, the invention relates to a method of making oriented calcium fluoride single crystal which comprises loading calcium fluoride feedstock on top of a seed crystal having a specific crystallographic orientation, heating the calcium fluoride feedstock to a temperature sufficient to form a melt, and growing a calcium fluoride crystal on the seed crystal by progressively moving the melt and the seed crystal through a temperature gradient zone having an axial temperature gradient in a range from approximately 2° C./cm to approximately 8° C./cm, wherein a growth direction of the calcium fluoride crystal substantially conforms to the crystallographic orientation of the seed crystal.

In another aspect, the invention relates to a calcium fluoride crystal for making optical elements for transmitting below 200-nm ultraviolet light having a [100] crystallographic orientation and a diameter greater than or equal to approximately 250 mm and exhibiting a mean birefringence no greater than approximately 1.2 nm/cm and inhomogeneity no greater than approximately 1.1 ppm.

Other features and advantages of the invention will be apparent from the following description and the appended claims.

### BRIEF DESCRIPTION OF DRAWINGS

FIG. 1A-1D illustrate a method of making [110]- and [100]-oriented calcium fluoride crystals according to an embodiment of the invention.

FIG. 2 is a graph showing centerline temperature and temperature gradient versus axial direction as crystal is formed.

FIG. 3 is a graph of an annealing and cooling profile for a calcium fluoride crystal according to an embodiment of the invention.

### DETAILED DESCRIPTION

The invention will now be described in detail with reference to a few preferred embodiments, as illustrated in the accompanying drawings. In the following description, numerous specific details are set forth in order to provide a thorough understanding of the invention. It will be apparent, however, to one skilled in the art that the invention may be practiced without some or all of these specific details. In other instances, well-known features and/or process steps have not been described in detail in order to not unnecessarily obscure the invention. The features and advantages of the invention may be better understood with reference to the drawings and discussions that follow.

In the background discussion, the inventors mentioned that [110]- and [100]-oriented CaF₂ single crystals are usually cut out of [111]-oriented CaF₂ single crystals. One would expect that like [111]-oriented CaF₂ single crystals, which are grown directionally using [111]-oriented seed crystals, it should be fairly straightforward to grow [110]- and [100]-oriented CaF₂ single crystals directionally using [110]- and [100]-oriented seed crystals, respectively. However, while not wishing to be bound by theory, the inventors argue herein that CaF₂ single crystals likely exhibit preferential growth in the [111] direction. According to the general solidification theory, once a nucleus is formed, crystal growth is limited by (a) the kinetics of atom attachment to the solid-liquid interface, (b) capillarity, and (c) diffusion of heat and mass. (Kurz, W. & Fisher, D. J. Fundamentals of Solidification. Aedermannsdorf-Suitzerland: Trans Tech Publications, 1986.) The relative importance of each of these factors depends on the substance in question and upon the growth conditions. For CaF₂ single crystals, growth in the [111] direction appears to be favored when the dominant control factor is kinetics of atom attachment to the liquid-solid interface or diffusion of heat and mass.

CaF₂ single crystal very likely grows with a microscopically faceted interface, which actually consists of many atomically-flat facets, due to its high (higher than metals) entropy of fusion. These atomically-flat facets generally choose a low-index plane with the lowest interface energy. As a result, the faceted growth mode tends to give different atomic attachment kinetics in different interface planes, and therefore might show an anisotropy in growth velocity for different orientations. Since CaF₂ crystals exhibit (111)-faceted surfaces it is reasonable to assume that the interface energy and attachment rate of CaF₂ are lowest in the (111) planes. From the standpoint of atomic attachment kinetics, it means that CaF₂ has very slow (axial) growth rate in [111] direction and very quick spreading (radial) speed in (111) plane. The growth in the [111] direction looks like layer-by-layer spreading in (111) plane. This growth mode makes it easier to maintain [111] orientation because any nucleation and growth in other directions will be suppressed by the rapid spreading (radial growth) in (111) plane.

However, growth in the [110] or [100] direction shows a different behavior from the one described above for the [111] direction in that the axial growth rate along the [110] or [100] direction could be higher than the radial growth rate along the solid-liquid interface. The slower radial growth will make the nucleation in other directions easier to propagate into the [110] or [100] direction and result in loss of singularity. It should be pointed out that this mechanism is applicable only for those growth processes where kinetics of atom attachment to the liquid-solid interface is the dominant control factor. From the point of view of diffusion of heat and mass, growing CaF₂ crystals along the [111] direction should also be easier than growing along the [110] or [100] direction. According to McCurdy, the thermal conductivity of CaF₂ is highest along the [111] direction and lowest along the [100] direction, with the difference being as much as 40% (McCurdy, A. K. “Phonon Conduction in Elastically Anisotropic Cubic Crystals.” Physical Review B 26 (1982): 6971.) This suggests that [111] might be the preferential direction for growing CaF₂ crystals.

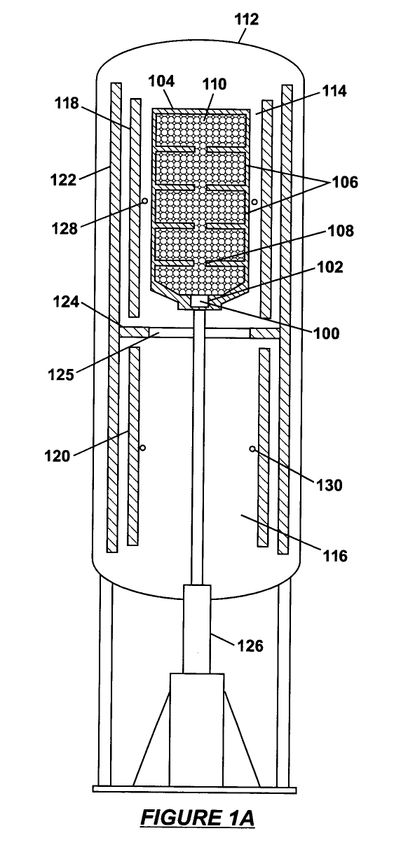

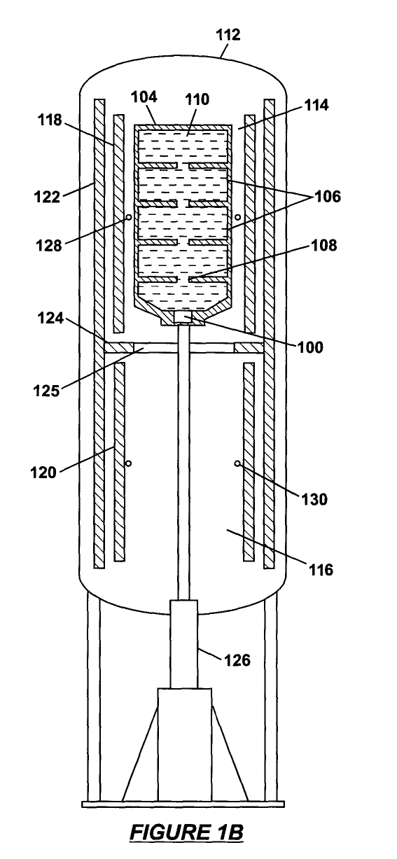

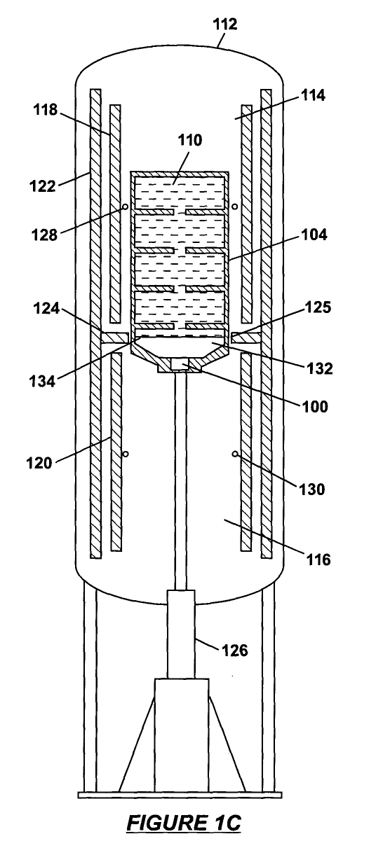

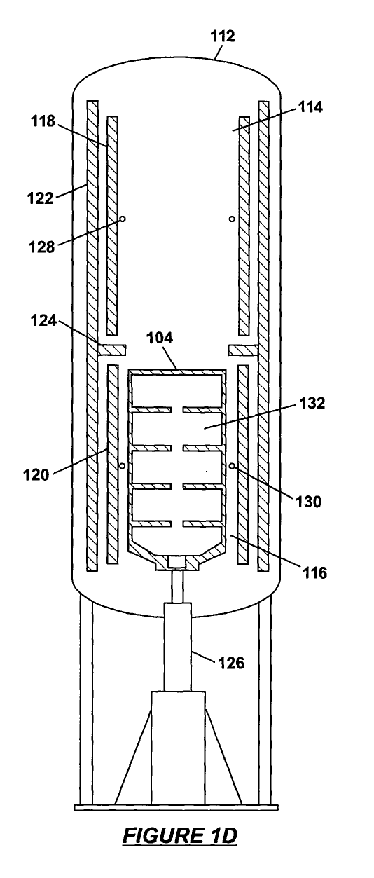

Embodiments of the invention provide a method of encouraging CaF₂ single crystal growth in or “near” the [110] or [100] direction. “Near” could be 3 to 5 degrees from the [110] or [100] direction but is preferably less than 1 degree from the [110] or [100] direction. The CaF₂ single crystals grown by the method of the invention have low stress-induced birefringence and low residual index inhomogeneity and can be used for making optical elements for 157-nm microlithography process and below 200-nm microlithography processes in general. Referring to FIG. 1A, the crystal growth process starts with a seed crystal 100 having [110] or [100] crystallographic orientation. A [110]-oriented seed crystal is used to grow [110] crystals, and a [100]-oriented seed crystal is used to grow [100]-oriented crystals. Typically, the seed crystal 100 is CaF₂ crystal. However, it may also be possible to use SrF₂ crystal or other materials having a similar phase and melting point to CaF₂. The seed crystal 100 is placed in a seed crystal holder 102 at the base of a crucible 104. In the illustrated embodiment, the crucible 104 has multiple crystal growth chambers 106. The crucible 104 may have any number of crystal growth chambers, typically in a range from 1 to 20. The crystal growth chambers 106 are in communication through holes 108 in the crystal growth chambers 106.

Each crystal growth chamber 106 contains CaF₂ feedstock 110. Preferably, the feedstock 110 is pretreated to remove impurities such as oxides that can have a detrimental effect on the optical performance of the grown crystal. An oxide scavenger may also be mixed with the feedstock 110. The crucible 104 with the feedstock 110 is supported in a vertical furnace 112. The vertical furnace 112 has a melting chamber 114 and an annealing chamber 116. Heaters 118, 120 are disposed in the melting and annealing chambers 114, 116, respectively, to maintain a prescribed temperature profile inside the melting and annealing chambers 114, 116. Insulation 122 may be provided around the heaters 118, 120 to assist in controlling the temperature in the melting and annealing chambers 114, 116. An annular diaphragm 124, made of insulating material, partially isolates the melting chamber 114 from the annealing chamber 116, creating a temperature gradient zone 125 between the melting chamber 114 and the annealing chamber 116. A lift mechanism 126 is coupled to the crucible 104. As an example, the lift mechanism 126 could be a fluid-powered actuator, such as a hydraulic or pneumatic actuator, or a mechanical actuator. The lift mechanism 126 can be operated to move the crucible 104 along the axial length of the furnace 112.

In one embodiment, temperature probes 128, 130 are provided inside the melting chamber 114 and annealing chamber 116, respectively. In operation, the output of the temperature probes 128, 130 may be supplied to a control system (not shown) that will automatically adjust the input to the heating elements 118, 120 such that a desired temperature profile is maintained in the melting and annealing chambers 114, 116. Preferably, the heaters 118, 120 can be controlled independently to achieve the desired temperature profiles inside the melting and annealing chambers 114, 116, respectively. The heaters 118, 120 may be made of a single heating element or multiple heating elements. Various alternate heater configurations are possible. See, for example, U.S. Pat. No. 6,562,126 (issued to Price) for possible alternate configurations.

In operation, the furnace 112 is hermetically sealed with vacuum, inert, fluorinating or other atmosphere suitable for crystal growth. The melting chamber 114 is then heated to a temperature sufficient to melt the feedstock 110 in the crucible 104, as shown in FIG. 1B. For example, for CaF₂, the temperature is typically set at about 1500° C. The crucible 104 with the molten feedstock 110 is slowly translated from the melting chamber 114, through the diaphragm 124, into the annealing chamber 116. The annealing chamber 116 is maintained at a temperature lower than the temperature of the melting chamber 114 so that there is a temperature gradient across the diaphragm 124. As shown in FIG. 1C, as the crucible 104 passes through the diaphragm 124, the molten feedstock 110 goes through the temperature gradient zone 125. As the crucible 104 passes through the temperature gradient zone 125, the temperature transition inside the molten feedstock 110 creates a solid-liquid growth front 134. The solid-liquid growth front 134 propagates inside the crucible 104, within the molten material 110, as long as the crucible 104 continues to move downwardly into the annealing chamber 116 to form crystal 132, which conforms to the crystallographic orientation of the seed crystal 100. In order to secure crystal growth in the orientation of the seed crystal 100, an initial position of the crucible 104 should be established so that the seed crystal 100 is partially, preferably half, melted prior to growing the crystal on the seed crystal.

The method of the invention is based in part on a contradictory fact about temperature gradient in crystal growth: high axial temperature gradient is good for growing crystals and bad for reducing stress-induced birefringence. This issue is particularly delicate for [110]- and [100]-oriented CaF₂ crystal growth because while the growth in these directions seems more difficult and therefore needs higher axial temperature gradient to ensure the singularity, the higher stress optical coefficient in these directions requires lower temperature gradient to produce a low stress-induced birefringence. It has been demonstrated that growing [110]- and [100]-oriented crystals under an axial temperature gradient above 1° C./cm, especially above 4° C./cm, is particularly preferred. It has also been demonstrated that the upper limit for growing [110]- and [100]-oriented single crystals with reduced stress-induced birefringence is 8° C./cm, preferably 6° C./cm. Combining these two opposite effects of axial temperature gradient on the singularity and stress-induced birefringence, a desired temperature gradient for growing [110]- and [100]-oriented crystals with a low stress birefringence is 2° C./cm to 8° C./cm, preferably 2° C./cm to 6° C./cm, more preferably 3° C./cm to 5° C./cm.

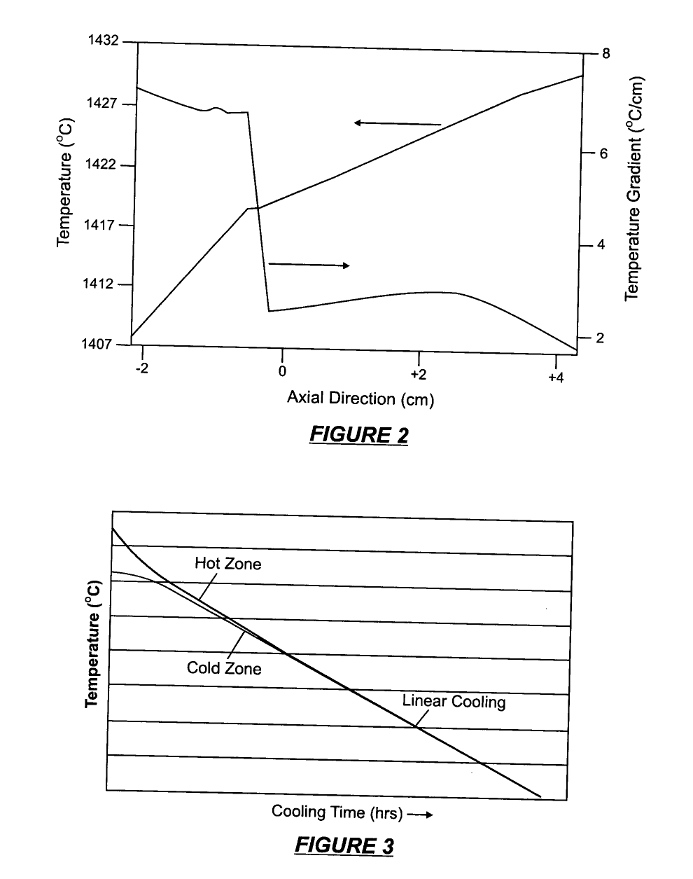

FIG. 2 is an example of a graph showing centerline temperature and temperature gradient as a function of axial direction as the crystal is grown. The zero position on the axial direction axis corresponds to the solid-liquid interface (134 in FIG. 1C). Returning to FIG. 1C, the probability of obtaining [110] or [100] crystals is enhanced when the solid-liquid interface is within, preferably in the middle of, the insulation (diaphragm 124) zone. By doing this, the stress-induced birefringence and small-angle grain boundaries can be reduced. The solid-liquid interface can be constrained within the insulation zone by appropriately choosing the temperature set-points of the melting chamber 114 and the annealing chamber 116. The axial temperature gradient is largely controlled by the temperatures of the melting chamber 114 and the annealing chamber 116 as well as the configuration of the furnace 112, the length of the insulation (diaphragm 124) zone, and the material and size of the crucible 104. For the temperature gradient at the solid-liquid interface 134, the growth velocity also has an effect. The temperature gradient in the crystal tends to increase with the growth velocity due to the latent heat released during solidification. However, this effect could be negligible if the translation speed of the crucible 104 during crystal growth is below 3 mm/hr. Preferably, the translation speed of the crucible 104 is in a range from 0.5 mm/hr to less than 3 mm/hr. Preferably, the translation speed does not vary by more than 0.1 mm/hr.

For illustration purposes, 300-mm diameter [110]- and [100]-oriented CaF₂ crystal growth experiments were carried out separately in a vertical Bridgman furnace. The feedstock was first mixed with scavengers and then put in a graphite crucible with a [110]-oriented CaF₂ seed crystal for [110] crystals and a [100]-oriented CaF₂ seed crystal for [100] crystals. The axial temperature gradient and the growth rate were set at around 6° C./cm and less than 3 mm/hr, respectively. Under these growth conditions, [110]- and [100]-oriented single crystals were successfully obtained. The crystals were cooled down using a conventional annealing process, typically including a rapid cooling rate of 6° C./hr from about 1500° C. down to about 1100° C., a slow cooling rate of about 1.5° C./hr from about 1100° C. down to about 750° C., an increased cooling rate of about 5° C./hr from about 750° C. to about 450° C., and an even faster cooling rate of 10° C./hr from about 450° C. to about 20° C. Table 1 below shows the inhomogeneity and birefringence measurements for the crystals.

TABLE 1

| | |
|---|---|
| Birefringence | Inhomogeneity (ppm) |

| | | | |
|---|---|---|---|
| Crystal | (nm/cm) | with | without |

| Orientation | Mean | RMS | Power | Power |
|---|---|---|---|---|
| [110] | 5.8 | 6.6 | 3.2 | 1.4 |
| [100] | 8.2 | 12.5 | 3.7 | 3.5 |

The stress-induced birefringence shown in Table 1 for [110]- and [100]-oriented CaF₂ single crystals is relatively high in comparison to that of [111]-oriented CaF₂ single crystals. The stress-induced birefringence of the [110]- and [100]-oriented CaF₂ single crystals could be reduced by growing the crystals at a lower axial temperature gradient and/or using an improved annealing process. A separate annealing process can also be used to reduce the birefringence in the crystals.

In one embodiment, an in-situ annealing method is used to cool the crystals once the crucible 104 is fully inside the annealing chamber 116, as shown in FIG. 1D. The in-situ annealing method uses two temperature regimes to cool down the crystal. The first temperature regime is between the melting temperature (approximately 1420° C.) and approximately 1200° C. In this temperature regime, a decreasingly fast cooling profile and an increasingly slow cooling profile are applied to the melting chamber 114 and the annealing chamber 116, respectively, to reduce or diminish the temperature difference between the melting chamber 114 and the annealing chamber 116 which is required for crystallization. This temperature difference is preferably less than 50° C., more preferably less than 30° C., at the first temperature regime. This step is designed to minimize the temperature gradient in the annealing chamber 116 as early as possible. After the primary cooling stage, a substantially constant cooling rate is applied to both zones from the first temperature (in a range from about 1300° C. to 1100° C., preferably in a range from about 1250° C. to 1150° C.) to a final temperature in a range from about 300° C. to about 20° C., more preferably to room temperature. As shown in FIG. 3, both cooling curves should be as smooth as possible to avoid any undesirable thermal disturbance. For crystals with a diameter greater than 250 mm, it has been demonstrated that desirable inhomogeneity and birefringence can be achieved using a cooling rate of less than 3° C./hr, preferably 2° C./hr or less in the linear portion of the annealing.

For illustration purposes, 300-mm diameter [100]-oriented CaF₂ crystal growth experiments were carried out in a vertical furnace. The feedstock was first mixed with scavengers and then put in a graphite crucible with a [100]-oriented CaF₂ seed crystal. The axial temperature gradient and the growth rate were set at around 6° C./cm and less than 3 mm/hr, respectively. Under these growth conditions, [100]-oriented single crystals were successfully obtained. The crystals were annealed in-situ using the linear annealing method described above. For the linear annealing method, the cooling rate after the initial cooling down of the melting and annealing chambers was approximately 2° C./hr. Table 2 below shows the inhomogeneity and birefringence measurements for the [100]-oriented single crystals.

TABLE 2

| | Birefringence | | | |
|---|---|---|---|---|
| Annealing | (nm/cm) | | Inhomogeneity (ppm) | |
| Method | Mean | RMS | with Power | without Power |
| Linear | 1.2 | 1.8 | 1.1 | 1.1 |
| Conventional | 8.2 | 12.5 | 3.7 | 3.5 |

The invention provides one or more advantages. First, [110]- and [100]-oriented CaF₂ single crystals can be grown economically. Secondly, combining an appropriate annealing method with the crystal growth method of the invention allows [110]- and [100]-oriented CaF₂ single crystals having low birefringence and low inhomogeneity to be manufactured. With the in-situ annealing method described above, [110]- and [100]-oriented CaF₂ single crystals having low birefringence and low inhomogeneity can be grown in a single furnace run. The results above show that birefringence as low as 1.2 nm/cm has been achieved for [100]-oriented CaF₂ single crystals. Birefringence may be further reduced by choosing a lower temperature gradient and cooling rate for the crystal growth and annealing, respectively. Multiple crystals can be grown in a single furnace run using a multi-chamber crucible (or a stack of single-chamber crucibles) to increase the yield of the crystal growth process. The grown [110]- or [100]-oriented CaF₂ single crystals can be used to design lens systems for below 200 nm microlithography.

While the invention has been described with respect to a limited number of embodiments, those skilled in the art, having benefit of this disclosure, will appreciate that other embodiments can be devised which do not depart from the scope of the invention as disclosed herein. Accordingly, the scope of the invention should be limited only by the attached claims.

What is claimed is:

1. A method of making an oriented calcium fluoride single crystal, comprising:
loading calcium fluoride feedstock on top of a seed crystal having a specific crystallographic orientation;
heating the calcium fluoride feedstock to a temperature sufficient to form a melt; and
growing a calcium fluoride crystal on the seed crystal by progressively moving the melt and the seed crystal through a temperature gradient zone having an axial temperature gradient in a range from approximately 2° C./cm to approximately 8° C./cm;
wherein a growth direction of the calcium fluoride crystal substantially conforms to the crystallographic orientation of the seed crystal.

2. The method of claim 1, wherein the seed crystal has [110] crystallographic orientation.

3. The method of claim 1, wherein the seed crystal has [100] crystallographic orientation.

4. The method of claim 1, wherein the axial temperature gradient is in a range from approximately 2° C./cm to approximately 6° C./cm.

5. The method of claim 1, wherein the axial temperature gradient is in a range from approximately 3° C./cm to approximately 5° C./cm.

6. The method of claim 1, wherein the seed crystal is partially melted to ensure that the growth direction of the calcium fluoride crystal substantially conforms to the crystallographic orientation of the seed crystal.

7. The method of claim 1, wherein a solid-liquid interface between the calcium fluoride crystal and the melt is constrained to be within the temperature gradient zone.

8. The method of claim 1, wherein the calcium fluoride crystal has a mean birefringence no greater than approximately 1.2 nm/cm and inhomogeneity no greater than approximately 1.1 ppm.

9. The method of claim 1, wherein the temperature gradient zone is created between a first zone and a second zone in a vertical furnace, the first zone having a higher temperature than the second zone.

10. The method of claim 9, wherein the calcium fluoride feedstock is heated in the first zone.

11. The method of claim 10, further comprising annealing the calcium fluoride crystal in the second zone.

12. The method of claim 11, wherein annealing the calcium fluoride crystal in the second zone comprises cooling the calcium fluoride crystal to a first temperature.

13. The method of claim 12, wherein the first temperature is in a range from approximately 1300° C. to approximately 1100° C.

14. The method of claim 11, wherein annealing the calcium fluoride crystal further comprises cooling the calcium fluoride crystal to a final temperature at a substantially constant cooling rate.

15. The method of claim 14, wherein the final temperature is in a range from approximately 300° C. to approximately 20° C.

16. The method of claim 14, wherein the final temperature is in a range from approximately 100° C. to approximately room temperature.

17. The method of claim 14, wherein the cooling rate is less than or equal to approximately 3° C./hr.

18. The method of claim 14, wherein the cooling rate is less than or equal to approximately 2° C./hr.

19. The method of claim 12, wherein cooling the calcium fluoride to a first temperature comprises applying a decreasingly fast cooling profile to the first zone and an increasingly slow cooling profile to the second zone to diminish a temperature difference between the first zone and the second zone.

20. The method of claim 1, wherein a translation speed of the melt through the temperature gradient zone is less than 3 mm/hr.

21. The method of claim 20, wherein the translation speed of the melt through the temperature gradient zone is in a range from approximately 0.5 mm/hr to less than approximately 3 mm/hr.

22. The method of claim 1, wherein a translation speed of the melt as it moves through the temperature gradient zone does not vary by more than approximately 0.1 mm/hr.

23. A calcium fluoride crystal for making optical elements for transmitting below 200-nm ultraviolet light having a [100] crystallographic orientation and a diameter greater than or equal to approximately 250 mm and exhibiting a mean birefringence no greater than approximately 1.2 nm/cm and inhomogeneity no greater than approximately 1.1 ppm.
